(19) United States
(12) Patent Application Publication
(10) Pub. No.: US 2008/0057677 A1
(43) Pub. Date: Mar. 6, 2008

(54) CHIP LOCATION IDENTIFICATION

(75) Inventors: Sylvie Charles, Bromont (CA); Timothy H. Daubenspeck, Colchester, VT (US); Jeffrey P. Gambino, Westford, VT (US); Robert Hannon, Wappingers Falls, NY (US); Ian D. Melville, Highland, NY (US); Christopher D. Muzzy, Burlington, VT (US); Wolfgang Sauter, Richmond, VT (US)

Correspondence Address: HOFFMAN, WARNICK & D'ALESSANDRO LLC, 75 STATE ST, 14TH FLOOR, ALBANY, NY, 12207, US

(73) Assignee: INTERNATIONAL BUSINESS MACHINES CORPORATION, Armonk, NY (US)

(21) Appl. No.: 11/470,355

(22) Filed: Sep. 6, 2006

(51) Int. Cl. H01L 21/78; H01L 23/544

(52) U.S. Cl. 438/460; 438/462; 257/797

(57) ABSTRACT

Chip location identification using dummy solder bead(s) is disclosed. A structure may include an integrated circuit (IC) chip including a plurality of solder beads for electrically coupling the IC chip to other structure, and a chip location identifier including at least one dummy solder bead on the IC chip, the chip location identifier representing a unique location of the IC chip in a wafer prior to dicing. The structure allows location tracking of an IC chip within a wafer without any additional processing, space, or mask levels. The structure can also be evaluated (visually or electrically) at the packaging level.

### BACKGROUND OF THE INVENTION

1. Technical Field

The invention relates generally to integrated circuit (IC) chip fabrication, and more particularly, to chip location identification using dummy solder bead(s).

2. Background Art

Integrated circuit (IC) chips are formed on wafers, which are then diced into individual IC chips. Once wafers are diced, they are picked and assembled into chip packages. At this point, it is not easily detectable where on the wafer an IC chip originated. However, there are several reasons why it is desirable to have traceability of where on a wafer an IC chip originated. For example, such information is useful for process learning so defects can be corrected, product dispositioning for known defects, qualification learning, engineering evaluation support (‘wafer striping’), etc.

One approach to provide chip location identification employs laser fuse identification. This approach, however, requires an additional fuse blow(s) to implement and a package tester for read-out. In addition, this approach is not qualified for new (low dielectric constant) technologies. Another approach employs electronic fuse identification (i.e., e-fuse ID or ECID). This approach is disadvantageous because it requires additional chip design, a wafer test (to blow fuses), a poly conductor mask (which cannot be used for CPI/packaging test sites) and also requires a package tester for read-out. Another approach includes wafer-level chip identification laser scribing. This approach requires additional laser scribing, creates mechanical damage and stress concentrations (and is not qualified) for flip chip plastic ball grid array (FC-PBGA), and cannot be read after packaging since typically the back side of the IC chip is covered. Each of the above-described approaches also are problematic because they require either additional space, processing and/or mask levels.

FIG. 1 shows an integrated circuit (IC) chip 10 including a conventional layout of solder beads 12, some times referred to as controlled collapse chip connection, or C4. IC chip 10 can be mounted using flip chip technology, which does not require any wire bonds. Instead, the final wafer processing step deposits solder beads 12 on the chip contact pads (under beads 12). After cutting the wafer into individual dice, IC chip 10 is then mounted upside down in/on the package (not shown) and solder beads 12 are reflowed. Flip chips then normally will undergo an underfill that covers the bottom side and sidewalls of the die. In some cases, dummy (i.e., inoperative) solder beads (not shown) are used for mechanical support and/or to maintain a uniform pattern density of solder beads.

### SUMMARY OF THE INVENTION

Chip location identification using dummy solder bead(s) is disclosed. A structure may include an integrated circuit (IC) chip including a plurality of solder beads for electrically coupling the IC chip to other structure, and a chip location identifier including at least one dummy solder bead on the IC chip, the chip location identifier representing a unique location of the IC chip in a wafer prior to dicing. The structure allows location tracking of an IC chip within a wafer without any additional processing, space, or mask levels. The structure can also be evaluated (visually or electrically) at the packaging level.

A first aspect of the invention provides a method comprising: providing a integrated circuit (IC) chip including a chip location identifier including at least one dummy solder bead on the IC chip, the chip location identifier representing a unique location of the IC chip in a wafer prior to dicing; and determining a location of the IC chip in the wafer prior to dicing based on the chip location identifier.

A second aspect of the invention provides a structure comprising: an integrated circuit (IC) chip including a plurality of solder beads for electrically coupling the IC chip to other structure; and a chip location identifier including at least one dummy solder bead on the IC chip, the chip location identifier representing a unique location of the IC chip in a wafer prior to dicing.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows an integrated circuit (IC) chip including a conventional layout of solder beads.

FIG. 2 shows a structure including an IC chip including a chip location identifier according to one embodiment of the invention.

FIG. 3 shows one embodiment of a formula for interpreting the chip location identifier.

FIG. 4 shows the structure of FIG. 2 including a chip package according to one embodiment of the invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

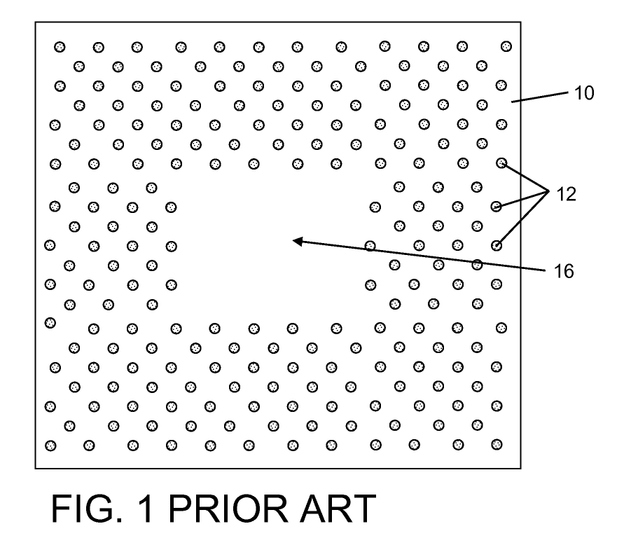

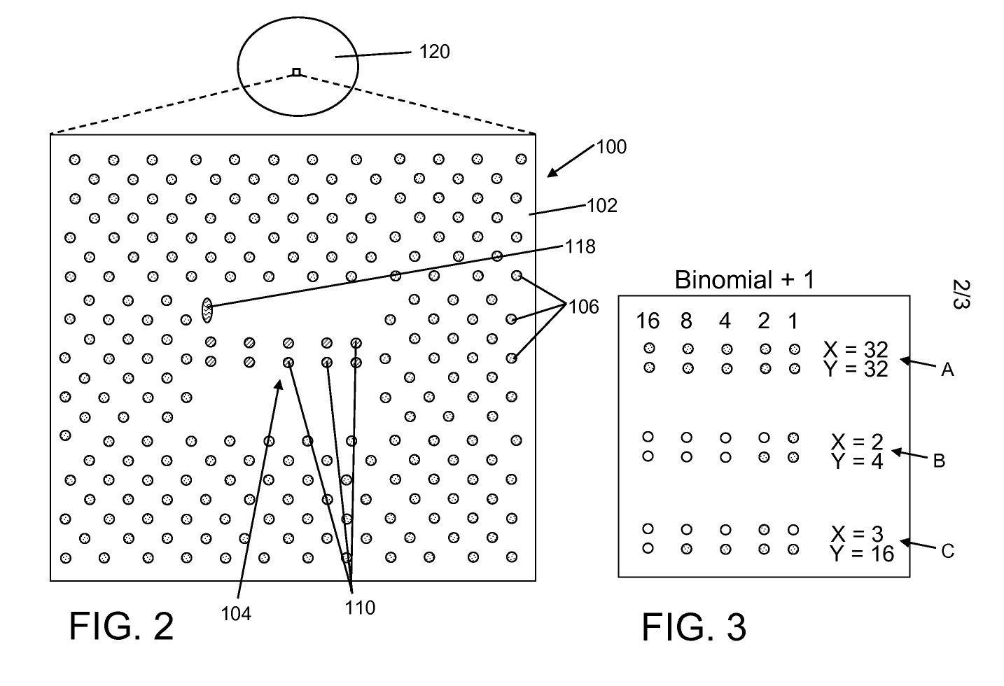

FIG. 2 shows a structure 100 including an integrated circuit (IC) chip 102 having a chip location identifier 104 according to one embodiment of the invention. As shown in FIG. 1, conventional IC chips 10 typically do not have a full array of solder beads 12 in a center portion 16 thereof. Accordingly, positioning of chip location identifier 104 at a center of IC chip 102 does not present a problem. IC chip 102 includes a plurality of (operative) solder beads 106 for electrically coupling IC chip 100 to other structure, e.g., a ball grid array. Solder beads 106 are operative for carrying signals, power, ground, etc. In contrast, chip location identifier 104 includes at least one dummy solder bead 110 on IC chip 102. A dummy solder bead, as used herein, means the solder bead is inoperative relative to the operation of IC chip 102, i.e., it carries no signal or power. A layout of at least one dummy solder bead 110 represents a unique location of IC chip 102 in a wafer 120 prior to dicing.

In one embodiment, chip location identifier 104 may include at least one start indicator dummy solder bead 118 for providing an indication of direction for chip location identifier 104. As indicated, a start indicator dummy solder bead 118 may have a different shape, e.g., oval, rectangular, or another shape, compared to other solder beads 106, 110 for easier identification.

Chip location identifier 104 may employ any manner of communicating using dots, i.e., dummy solder beads 110. In the example shown in FIG. 2, chip location identifier 104 includes two rows of five dummy solder beads 110, each row indicating a coordinate of IC chip 102 in wafer 120. For example, an upper row may indicate an X-coordinate of IC chip 102 in wafer 120, and the lower row may indicate a Y-coordinate of IC chip 102 in wafer 120. As shown in FIG. 3, in one embodiment, chip location identifier 104 may include dummy solder bead(s) 110 representing the unique location using a binomial +1 formula. Three IC chips' A, B and C chip location identifiers are shown in FIG. 3. Based on the binomial +1 formula indicated, IC chip A was located at X-Y position 32, 32; IC chip B was located at X-Y position 2, 4, and IC chip C was located at X-Y position 3, 16. In an alternative embodiment, a binomial formula may be used. Other formulae may also be employed within the scope of the invention. It is also understood that chip location identifier 104 needs not include rows or any other particular arrangement. As stated above, any manner of communicating using dots, i.e., dummy solder beads 110, is considered within the scope of the invention.

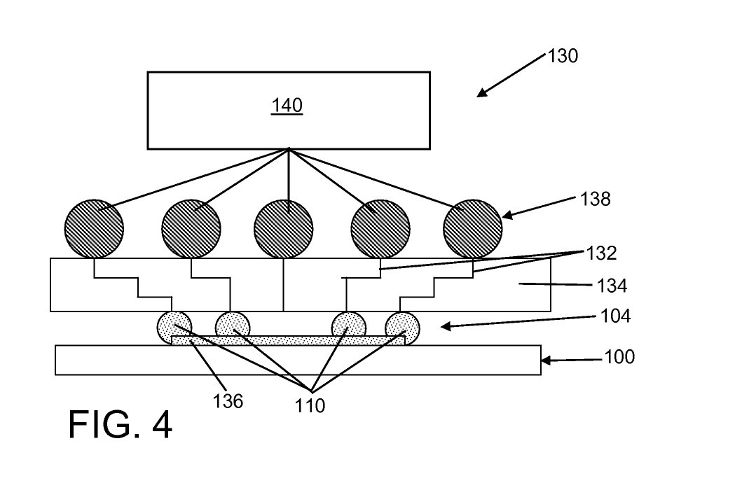

Chip location identifier 104 may be determined using a number of different mechanisms. In one embodiment, chip location identifier 104 is determined by x-raying IC chip 102 (or a chip package 130 (FIG. 4) in which it is positioned). In another embodiment, shown in FIG. 4, structure 100 may include a chip package 130 for IC chip 102. Chip package 130 may include an electrical connection 132 (i.e., through, for example, a laminate 134) to each of at least one dummy solder beads 110. In one embodiment, dummy solder beads 110 are shorted together with metallization layer 136. In this fashion, chip location identifier 104 may be obtained by evaluating electrical connections 132 to chip location identifier 104, e.g., via a ball grid array 138 and package tester 140.

In operation, IC chip 102 is provided including chip location identifier 104 having at least one dummy solder bead 110 thereon, which representing a unique location of IC chip 104 in wafer 120 prior to dicing. A location of IC chip 102 in wafer 120 prior to dicing can then be determined based on chip location identifier 104. The determining may include obtaining chip location identifier 104, e.g., by electrically using package tester 140 or via x-raying. A start indicator dummy solder bead 118 may be used to identify a direction in which chip location identifier 104 should be read.

The method and structure as described above are used in the fabrication of IC chips. The resulting IC chips can be distributed by the fabricator in raw wafer form (that is, as a single wafer that has multiple unpackaged chips), as a bare die, or in a packaged form. In the latter case, the IC chip is mounted in a single chip package (such as a plastic carrier, with leads that are affixed to a motherboard or other higher level carrier) or in a multi-chip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method comprising:
providing a integrated circuit (IC) chip including a chip location identifier including at least one dummy solder bead on the IC chip, the chip location identifier representing a unique location of the IC chip in a wafer prior to dicing; and
determining a location of the IC chip in the wafer prior to dicing based on the chip location identifier.

2. The method of claim 1, wherein the determining includes obtaining the chip location identifier by x-raying the IC chip.

3. The method of claim 1, wherein the determining includes obtaining the chip location identifier by evaluating an electrical connection to the chip location identifier.

4. The method of claim 1, wherein the chip location identifier represents the unique location using one of: a binomial and binomial +1 formula.

5. The method of claim 1, wherein the providing further includes providing at least one start indicator dummy solder bead.

6. A structure comprising:
an integrated circuit (IC) chip including a plurality of solder beads for electrically coupling the IC chip to other structure; and
a chip location identifier including at least one dummy solder bead on the IC chip, the chip location identifier representing a unique location of the IC chip in a wafer prior to dicing.

7. The structure of claim 6, further comprising a chip package including an electrical connection to each of the at least one dummy solder beads.

8. The structure of claim 6, wherein the chip location identifier represents the unique location using one of: a binomial and binomial +1 formula.

9. The structure of claim 6, further comprising at least one start indicator dummy solder bead.
